(19) United States
(12) Patent Application Publication
(10) Pub. No.: US 2006/0181855 A1
(43) Pub. Date: Aug. 17, 2006

(54) Heat generation assembly with cooling structure

(75) Inventors: Chiang-Han Chen, Taipei (TW); Hung-Chin Liao, Taipei (TW); Min-Hsun Shen, Taipei (TW)

Correspondence Address: G. LINK Co., LTD, 3550 Bell Road, MINOOKA, IL, 60447, US

(73) Assignee: ASIA VITAL COMPONENT CO., LTD.

(21) Appl. No.: 11/056,098

(22) Filed: Feb. 14, 2005

(51) Int. Cl. H05K 7/20

(52) U.S. Cl. 361/717

(57) ABSTRACT

A heat generation assembly with heat removing structure includes a heat generating component and a cooling unit disposed at a lateral side of the heat generating component. The heat generating component contacts with the cool unit to allow the cooling unit occurring energy transfer and the heat is changed to electric energy. Hence, the heat generated during the heat generating component being in operation is removed effectively.

### BACKGROUND OF THE INVENTION

1. Field of the Invention

The present invention is related to a heat generation assembly with heat removing structure and particularly to a heat generating component, which is associated with a cooling device, being capable of transferring the heat for lowering temperature of the heat generating part and supplying electric power.

2. Brief Description of the Related Art

Due to various apparatus frequently producing heat during being in operation, heat-removing device has to be utilized to dissipate the generated heat energy. The most currently used heat-removing device is the cooling fan. But, the cooling fan only dissipates limited amount of heat and extremely high temperature heat energy is incapable of being removed by the cooling fan and it often results in shutdown or damage of the product.

Taiwanese Patent Official Gazette No. 260325 discloses an improved cooling and temperature control device, which provides a fan at the top of the cooling fins and a cooling device under the cooling fins. The cooling fins have a plurality of jut pieces at the surfaces thereof and the jut pieces are arranged in order on the surfaces with an end of the respective jut piece extending outward the respective cooling fin and the contact surface of the fan. In addition, a slot is provided at the cooling fins for being inserted with a control circuit board. Further, a temperature sensor 12 is disposed at an edge of a lower conductive plate 42 of the cooling device 40 such that the temperature sensor 12 contacts with a temperature controlled object to feed back a correct sensed temperature so as to reach a purpose of temperature control.

However, the structure formed with the control circuit board, the temperature sensor and the cooling device has a cooing surface adhered a CPU and a heat dissipation surface joined to a fan for removing heat from the heat generating object. When the power is off, the residue electric charges still acts to the cooling device continuously to result in the cooling surface on the cooling device keeping sucking heat so as to occur condensation phenomenon and lead to short circuit. Further, the preceding improved cooling and temperature control device has to be supplied power for normal working so that the prior art obviously is unable to regenerate and reuse the energy under the condition of limited energy and material with high cost.

Besides, the traditional art provides ceramic material to seal and pack the CPU with a metal upper cover and a radiator is joined to the metal upper cover. Heat source, which generates during the CPU being in operation, passes through the ceramic package and the metal cover and then the fan forces air to flow in a way of convection so as to cool the CPU. But, the prior art has the following shortcomings:

1. The fan consumes a great deal of electrical energy and the preceding heat source is easy to increase the ambient temperature to influence heat dissipation of other parts.

2. Large quantity of metal has to be used for making the fan, the metal cover and the heat dissipation device and it results in cost increase and resource waste.

3. The preceding type cooling structure has to be changed design in accordance with heat increase rapidly resulting from higher clock frequency of the CPU and it takes long time before the product can be available on the market.

### SUMMARY OF THE INVENTION

An object of the present invention is to provide a heat generation assembly with heat removing structure in which an energy transfer part composed of a heat generating component associated with a cooling unit (or called cooling core, thermoelectric element, heat pump, Peltier cooler or thermoelectric cooler) to remove heat energy from the heat generating component by way of energy transfer function provided by the cooling unit and to offer power to other heat dissipation devices by way of electricity produced by the cooling device for saving resource.

Another object of the present invention is to provide a heat generation assembly with heat removing structure with which heat from the heat generating component can be transmitted to the cooling unit directly to enhance effect of heat dissipation tremendously.

A further object of the present invention is to provide a heat generation assembly with heat removing structure with which heat is moved to reduce temperature of the heat generating object.

A further object of the present invention is to provide a heat generation device with heat removing structure with which the hot surface thereof contacts the heat generating object to prevent from short circuit due to condensation phenomenon resulting from the cold surface of the cooling device sucking heat continuously.

### BRIEF DESCRIPTION OF THE DRAWINGS

The detail structure, the applied principle, the function and the effectiveness of the present invention can be more fully understood with reference to the following description and accompanying drawings, in which:

FIG. 1 is an exploded perspective view of the first embodiment of a heat generation component with cooling structure according to the present invention;

FIG. 2 is an assembled perspective view of FIG. 1;

FIG. 3 is a sectional view of the second embodiment of a heat generation component with cooling structure according to the present invention;

FIG. 4 is a sectional view of the third embodiment of a heat generation component with cooling structure according to the present invention; and

FIG. 5 is a sectional view of the fourth embodiment of a heat generation component with cooling structure according to the present invention.

### DETAILED DESCRIPTION OF THE INVENTION

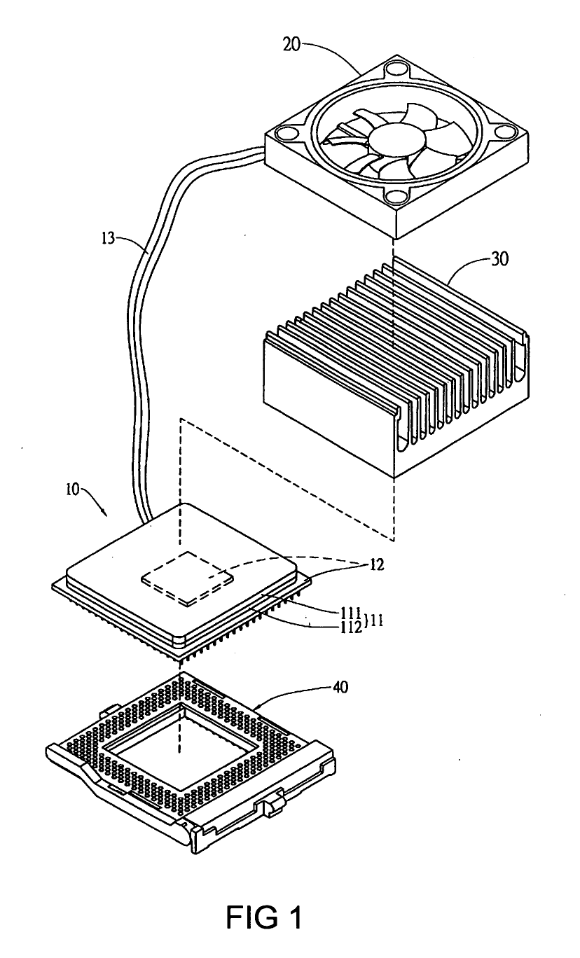

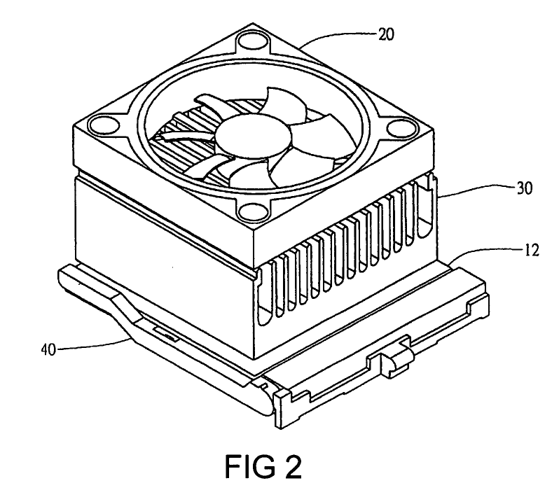

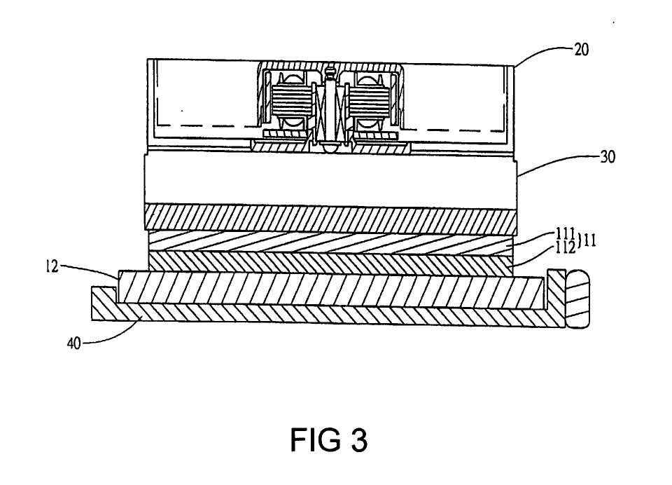

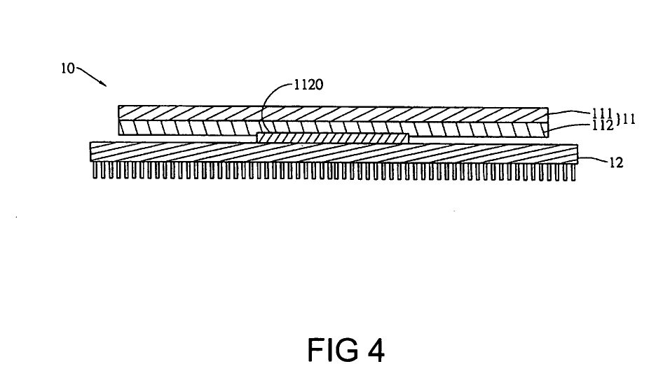

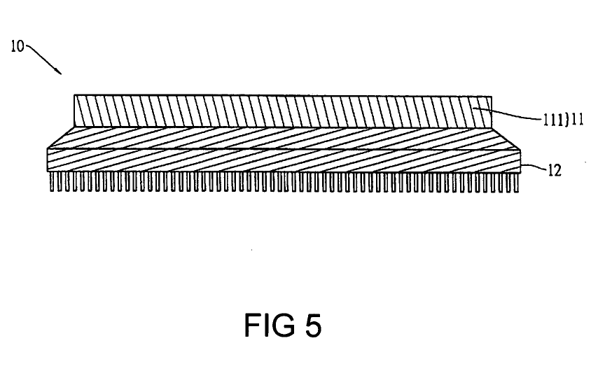

Referring to FIGS. 1, 2 and 3, the first embodiment of a heat generation assembly with cooling structure according to the present invention includes an energy transfer part 10, a fan 20 and a heat removing block 30. The energy transfer part 10 further includes a cooling unit 11 and a heat generating component 12. The heat generating component 12 is joined to the cooling unit 11 with contacting, adhering or any other appropriate joining way and due to Peltier effect, heat conducts from a side of the cooling unit 11 to another side thereof to constitute temperature difference between a first substrate 111 (cold surface) and a second substrates 112 (hot surface) and the cooling unit 11 occurs energy transfer to allow heat changing to electric energy. That is, the heat generating component 12 is joined to the second substrate 112 and the cooling unit 11 occurs energy transfer to change the heat energy to the electric energy with the first substrate 111 providing the cold surface. The heat generating component 12 can be any type of heat generating object and a typical example of the heat generating component 12 is the central processing unit (CPU) in a computer, integrated circuit chip or signal amplifying assembly or a prior packed chip thereof or an exposed piece. Alternatively, the heat generating component 12 can be attached to a base 40. Besides, the second substrate 112 can be provided with a recess 1120 to receive the heat generating component 12 as shown in FIG. 4 or the heat generating component 12 with a packing body is joined to the cooling unit 11 as shown in FIG. 5 without the second substrate 112.

Besides, the cooling unit 11 can provide a conductive member 13 for connecting with fan 20 or any other periphery device directly or indirectly and the fan 20 is driven with the electric energy produced by the cold unit 11.

The cooling unit 11 can contact with or is joined to the heat removing block 30 with the first substrate 111 (cold surface) thereof such that low temperature at the first substrate 111 can be conducted to the heat removing block 30. The fan 20 can be attached to the heat removing block 30 to drive or guide cooler air after passing through the heat removing block 30 toward other parts performing heat exchange or lowering the whole ambient temperature. In this way, it is capable of lowering working temperature of the heat generating component 12 and recycling or utilizing energy.

As the foregoing, the heat generation assembly with cooling structure according to the present invention has the following advantages:

1. Non-packed heat generating component 12 contacting with the cold unit 11 allows heat of the heat generating component 12 being transmitted to the cooling unit 11 with part of heat dissipating to the air so that packing cost can be lowered in addition to better heat transfer being obtained and deficiency of conventional packing technique not easy to remove heat being overcome.

2. Due to the energy transfer part 10 providing energy change, electricity created can be used by other heat dissipation devices to utilize energy sufficiently such that it is not necessary to provide external power supply and the production cost can be reduced.

3. The cooling unit 11 contacting with the heat generating object with the hot surface thereof can overcome problem of condensation occurring in the conventional art during power off to avoid short circuit so that it enhances work safety.

4. The air cooled by the cold surface of the energy transfer part 10 performs heat exchange with other parts or lowers down the whole ambient temperature so that the fan 20 and the heat removing block 30 can provide smaller surface areas to reduce material cost. Further, it is not necessary for the fan 20 to run under the full power so that it is able to extend life span of the fan.

5. The present invention is suitable for different heat generating components 12 so that it is not required to redesign heat dissipation device for the specific heat generating component 12 and cost for research and development can be saved tremendously.

While the invention has been described with referencing to preferred embodiments thereof, it is to be understood that modifications or variations may be easily made without departing from the spirit of this invention, which is defined by the appended claims.

What is claimed is:

1. A heat generation assembly with heat removing structure, comprising:
a heat generating component; and
a cooling unit, being attached to a lateral side of the heat generating component.

2. The heat generation assembly with heat removing structure as defined in claim 1, wherein a heat removing block is joined to the cold unit.

3. The heat generation assembly with heat removing structure as defined in claim 2, wherein a fan set is attached to the heat removing block.

4. The heat generation assembly with heat removing structure as defined in claim 1, wherein a first substrate is disposed at a lateral side of the cooling unit.

5. The heat generation assembly with heat removing structure as defined in claim 1, wherein a second substrate is disposed at a lateral side of the cooling unit.

6. The heat generation assembly with heat removing structure as defined in claim 5, wherein the heat generating component contacts with the second substrate.

7. The heat generation assembly with heat removing structure as defined in claim 4, wherein the first substrate contacts with a heat removing block.

8. The heat generation assembly with heat removing structure as defined in claim 1, wherein the heat generating component is a central processing unit.

9. The heat generation assembly with heat removing structure as defined in claim 1, wherein the heat generating component is a signal amplifying part.

10. The heat generation assembly with heat removing structure as defined in claim 1, wherein the heat generating component is a bare chip.

11. The heat generation assembly with heat removing structure as defined in claim 1, wherein the heat generating component is a non-packed piece.

12. The heat generation assembly with heat removing structure as defined in claim 3, wherein the cooling unit has a conductor.

13. The heat generation assembly with heat removing structure as defined in claim 12, wherein the conductor is connected to a fan.

14. The heat generation assembly with heat removing structure as defined in claim 1, wherein the heat generating component is an integrated circuit board.
